(19) United States
(12) Patent Application Publication
(10) Pub. No.: US 2024/0206261 A1
(43) Pub. Date: Jun. 20, 2024

(54) ORGANIC LIGHT EMITTING DISPLAY DEVICE

(71) Applicant: LG Display Co., Ltd., Seoul (KR)

(72) Inventors: KyungYun KANG, Seoul (KR); Dongik KIM, Goyang-si (KR); HeeSuk PANG, Paju-si (KR)

(21) Appl. No.: 18/515,098

(22) Filed: Nov. 20, 2023

(30) Foreign Application Priority Data
Dec. 20, 2022 (KR) 10-2022-0178909

(51) Int. Cl. H10K 59/131; H10K 59/60

(52) U.S. Cl. CPC H10K 59/131; H10K 59/60

(57) ABSTRACT

Provided is an organic light emitting display device. The organic light emitting display device comprises a substrate including a display area; and pixels disposed in the display area on the substrate, wherein the display area includes a sensor area including light-transmissive areas, wherein the sensor area includes a transparent electrode disposed between the pixels, and wherein the transparent electrode overlaps the light-transmissive areas. Accordingly, a cathode may be removed without any additional process or equipment.

### CROSS-REFERENCE TO RELATED APPLICATIONS

This application claims the benefit of and priority to Korean Patent Application No. 10-2022-0178909 filed on Dec. 20, 2022, in the Republic of Korea, the entire contents of which are hereby expressly incorporated by reference into the present application.

### BACKGROUND

### Technical Field

The present disclosure relates to an organic light emitting display device in which a camera or sensor is disposed below a display area.

### Description of the Related Art

Recently, as our society advances toward an information-oriented society, the field of display devices for visually expressing an electrical information signal has rapidly advanced. Various display devices having excellent performance in terms of thinness, lightness, and low power consumption, are being developed correspondingly.

Among the display devices, an organic light emitting display device (OLED) does not include a separate light source, unlike a liquid crystal display device (LCD) having a backlight. Therefore, the organic light emitting display device can be manufactured to be light and thin, is advantageous in processing, and has an advantage of low power consumption due to low voltage driving. Above all, the organic light emitting display device includes a self-light emitting element and can have each layer formed of a thin organic thin film. Accordingly, it has excellent flexibility and elasticity compared to other display devices, and thus can be advantageously implemented as a flexible display device or a transparent display device.

Meanwhile, the display device has a display area where an image is substantially displayed and a bezel area which is a non-display area where an image is not substantially displayed because it is covered by a light blocking member or the like. A display element for displaying an image is disposed in the display area, and various lines or driving circuits for driving the display element are disposed in the bezel area. The display device includes a camera, a speaker, and various sensors to provide various functions, and these components are also disposed in the bezel area.

Recently, studies for reducing a bezel area have been actively conducted in order to make a design of the display device beautiful and to provide a wide screen as large as possible within a limited size of the display device. Correspondingly, technologies have been suggested in which components such as a camera and a sensor that are conventionally disposed in the bezel area, are disposed in the display area but they are disposed on a rear surface of a display panel so that images can be displayed smoothly.

### BRIEF SUMMARY

A technical benefit to be achieved by the present disclosure is to provide an organic light emitting display device capable of increasing light transmittance in an area from which a cathode is removed by removing the cathode disposed on an upper side of an organic light emitting display panel having a bottom emission structure.

In addition, a technical benefit of the present disclosure is to provide an organic light emitting display device in which an absorption rate of light incident on a camera or sensor is improved by removing a cathode functioning as a reflective layer in a bottom emission structure using a thermal electrode and then disposing the camera or sensor in an area where the cathode is removed.

Benefits of the present disclosure are not limited to the above-mentioned benefits, and other benefits, which are not mentioned above, can be clearly understood by those skilled in the art from the following descriptions.

An organic light emitting display device according to an exemplary embodiment of the present disclosure includes a substrate including a display area; and a plurality of pixels disposed in the display area on the substrate, wherein the display area includes a sensor area including a plurality of light-transmissive areas, wherein the sensor area includes a transparent electrode disposed between the plurality of pixels, and wherein the transparent electrode overlaps the plurality of light-transmissive areas. An organic light emitting display device according to another exemplary embodiment of the present disclosure includes a substrate including a display area; and a plurality of pixels disposed in the display area on the substrate, wherein the display area includes a sensor area including a plurality of light-transmissive areas, wherein the sensor area includes a transparent electrode disposed between the plurality of pixels, and wherein the plurality of light-transmissive areas are formed by applying Joule heating to the transparent electrode.

Other detailed matters of the exemplary embodiments are included in the detailed description and the drawings.

An organic light emitting display device according to embodiments of the present disclosure may have excellent light transmittance in light-transmissive areas corresponding to a location of a camera or sensor. As light transmittance is improved in the light-transmissive areas, the camera or sensor can transmit or absorb more light irradiated in a direction of the camera or sensor.

According to the present disclosure, process optimization can be promoted by removing a cathode without any additional process or equipment.

The effects according to the present disclosure are not limited to the contents exemplified above, and more various effects are included in the present specification.

### BRIEF DESCRIPTION OF THE SEVERAL VIEWS OF THE DRAWINGS

FIG. 1 is a block diagram illustrating a display device according to an exemplary embodiment of the present disclosure.

FIG. 2 is a circuit diagram illustrating an example of a sub-pixel of the display device according to an exemplary embodiment of the present disclosure.

FIG. 3 is a schematic plan view of an organic light emitting display device according to an exemplary embodiment of the present disclosure.

FIG. 4 is an enlarged plan view illustrating an implementation example of area A1 of FIG. 3.

FIG. 5 is an enlarged plan view illustrating a first implementation example of area A2 of FIG. 3.

FIG. 6 is an enlarged plan view illustrating a second implementation example of the area A2 of FIG. 3.

FIG. 7 is an enlarged plan view illustrating a third implementation example of the area A2 of FIG. 3.

FIG. 8 is an enlarged plan view illustrating a fourth implementation example of the area A2 of FIG. 3.

FIG. 9 is an enlarged plan view illustrating a fifth implementation example of the area A2 of FIG. 3.

FIG. 10 is a plan view illustrating an organic light emitting display device according to another exemplary embodiment of the present disclosure.

FIG. 11 is an enlarged plan view illustrating an implementation example of area A2 including an auxiliary line of FIG. 10.

FIG. 12 is a cross-sectional view of area B1 of FIG. 11.

FIG. 13 is a cross-sectional view of area B2 of FIG. 11.

FIG. 14 is a cross-sectional view of the display device taken along line I-I′ of FIG. 11.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the element or layer may be interposed directly on the another element or layer, or the other element or layer may be interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Transistors used in organic light emitting display devices according to exemplary embodiments of the present disclosure may be implemented as one of n-channel transistors (NMOS) and p-channel transistors (PMOS). The transistor may be implemented as an oxide semiconductor transistor having an oxide semiconductor as an active layer or a low temperature poly-silicon (LTPS) transistor having LTPS as an active layer. The transistor may include at least a gate electrode, a source electrode, and a drain electrode. The transistor may be implemented as a thin film transistor (TFT) on a display panel. In the transistor, carriers flow from the source electrode to the drain electrode. In the case of the n-channel transistor (NMOS), since carriers are electrons, a source voltage may have a voltage level lower than that of a drain voltage so that the electrons may flow from the source electrode to the drain electrode. In the n-channel transistor (NMOS), current flows in a direction from the drain electrode to the source electrode, and the source electrode may be an output terminal. In the case of the p-channel transistor (PMOS), since carriers are holes, a source voltage may have a voltage level higher than that of a drain voltage so that the holes may flow from the source electrode to the drain electrode. In the p-channel transistor (PMOS), since the holes flow from the source electrode to the drain electrode, current flows from a source electrode to a drain electrode of the transistor, and the drain electrode may be an output terminal. Accordingly, it should be noted that the source electrode and drain electrode of the transistor are not fixed because the source electrode and drain electrode may change according to a voltage applied thereto. In the disclosure, descriptions are made assuming that the transistor is an n-channel transistor (NMOS), but it is not limited thereto, and a p-channel transistor may be used therefor and accordingly, a circuit configuration may be changed.

Gate signals of the transistors used as switching elements may swing between a gate-on voltage and a gate-off voltage. The gate-on voltage may be set to a voltage higher than a threshold voltage (Vth) of the transistor, and the gate-off voltage may be set to a voltage lower than the threshold voltage (Vth) of the transistor. The transistor may be turned on in response to the gate-on voltage, while being turned off in response to the gate-off voltage. In the case of the n-channel transistor (NMOS), the gate-on voltage may be a gate high voltage (VGH), and the gate-off voltage may be a gate low voltage (VGL). In the case of the p-channel transistor (PMOS), the gate-on voltage may be the gate low voltage (VGL), and the gate-off voltage may be the gate high voltage (VGH).

Hereinafter, various embodiments of the present disclosure will be described in detail with reference to the accompanying drawings.

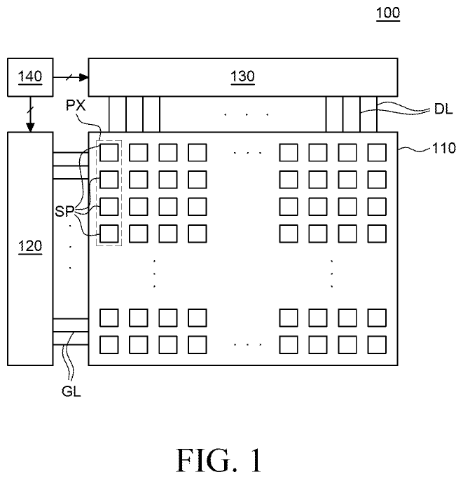

FIG. 1 is a block diagram illustrating a display device according to an exemplary embodiment of the present disclosure.

Referring to FIG. 1, a display device 100 according to an exemplary embodiment of the present disclosure may include a display panel 110, a gate driver 120, a data driver 130, and a timing controller 140.

The display panel 110 (or pixel unit or display unit) may display an image. The display panel 110 may include various circuits, signal lines, and light emitting elements that are disposed on a substrate. The display panel 110 is divided by a plurality of data lines DL and a plurality of gate lines GL that cross each other, and may include a plurality of pixels PX that are connected to the plurality of data lines DL and the plurality of gate lines GL.

The display panel 110 may include a display area in which an image is displayed and a non-display area which is located outside the display area and in which various signal lines or pads are formed. The display panel 110 may be implemented as a display panel used in various display devices such as a liquid crystal display device, an organic light emitting display device, and an electrophoretic display device. Hereinafter, the display panel 110 will be described as a panel used in an organic light emitting display device, but embodiments of the present disclosure are not limited thereto.

The display panel 110 may include the plurality of pixels PX disposed on the display area. Each of the plurality of pixels PX may be electrically connected to a corresponding gate line among the gate lines GL and a corresponding data line among the data lines DL. Accordingly, a gate signal and a data signal may be applied to each of the pixels PX through the gate line and the data line. Further, each of the pixels PX may implement a gray level by the applied gate signal and data signal, and finally, an image may be displayed on the display area according to the gray level displayed by each of the pixels PX.

Also, each of the plurality of pixels PX may include a plurality of sub-pixels SP. The sub-pixels SP included in one pixel PX may emit light of different colors. For example, the sub-pixels SP may include a red sub-pixel, a green sub-pixel, a blue sub-pixel, and a white sub-pixel, but are not limited thereto. The plurality of sub-pixels SP may constitute the pixels PX. That is, the red sub-pixel, the green sub-pixel, the blue sub-pixel, and the white sub-pixel may constitute one pixel PX, and the display panel 110 may include the plurality of pixels PX.

The timing controller 140 (or timing control circuit) may receive timing signals such as a vertical synchronization signal, a horizontal synchronization signal, a data enable signal, and a dot clock signal through a receiving circuit such as an LVDS or TMDS interface, which is connected to an outside (e.g., a host system). The timing controller 140 may generate and output timing control signals for controlling the data driver 130 and the gate driver 120 based on the timing signal input thereto.

The data driver 130 (or data driving circuit) may supply data signals to the plurality of sub-pixels SP. To this end, the data driver 130 may include at least one source drive integrated circuit (IC). The source drive IC may receive digital video data and a source timing control signal from the timing controller 140. The source driver IC may convert the digital video data into gamma voltages in response to the source timing control signal to generate data signals and supply the data signals to the sub-pixels SP through the data lines DL of the display panel 110. The source driver IC may be connected to the data lines DL of the display panel 110 through a chip on glass (COG) process or a tape automated bonding (TAB) process. In addition, the source drive IC may be formed on the display panel 110 or may be formed on a separate PCB board and connected to the display panel 110.

The gate driver 120 (or gate driving circuit, scan driving unit, or scan driving circuit) may supply gate signals to the plurality of sub-pixels SP. The gate driver 120 may include a level shifter and a shift register. The level shifter may shift a level of a clock signal that is input as a transistor-transistor logic (TTL) level and then, supply it to the shift register. The shift register may be formed in the non-display area of the display panel 110 by a gate in panel (GIP) method, but the present disclosure is not limited thereto. The shift register may be configured to include a plurality of stages for shifting and outputting the gate signals in response to the clock signal and a driving signal. The plurality of stages included in the shift register may sequentially output the gate signals through a plurality of output terminals.

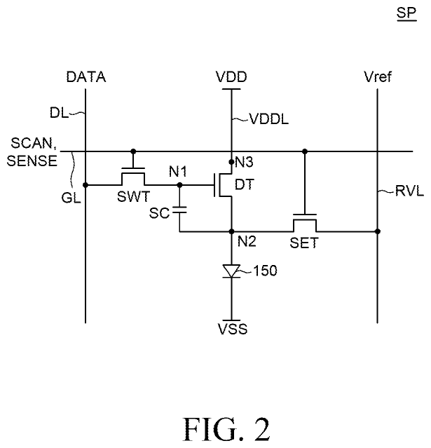

Hereinafter, a driving circuit (pixel circuit) for driving one sub-pixel SP will be described in more detail with reference to FIG. 2.

FIG. 2 is a circuit diagram illustrating an example of a sub-pixel.

Meanwhile, FIG. 2 illustrates a circuit diagram of one sub-pixel SP among the plurality of sub-pixels SP included in the display device 100 described with reference to FIG. 1.

Referring to FIG. 2, the sub-pixel SP may include a switching transistor SWT, a sensing transistor SET, a driving transistor DT, a storage capacitor SC, and a light emitting element 150.

The light emitting element 150 may include an anode, a light emitting layer, and a cathode. For example, the light emitting layer may be an organic layer, and the organic layer may include various organic layers such as a hole injection layer, a hole transport layer, an organic light emitting layer, an electron transport layer, and an electron injection layer. The anode of the light emitting element 150 may be connected to the driving transistor DT (e.g., an output terminal of the driving transistor DT), and a low potential voltage VSS may be applied to the cathode of the light emitting element 150.

Meanwhile, in FIG. 2, descriptions are made based on that the light emitting element 150 is an organic light emitting diode, but embodiments of the present disclosure are not limited thereto. For example, the light emitting element 150 may be an inorganic light emitting diode (e.g., LED).

The driving transistor DT may supply driving current to the light emitting element 150 so that the light emitting element 150 can emit light. The driving transistor DT may include a gate electrode that is connected to a first node N1, a source electrode (or output terminal) that is connected to a second node N2, and a drain electrode (or input terminal) that is connected to a third node N3. The first node N1, to which the gate electrode of the driving transistor DT is connected, may be connected to the switching transistor SWT. The third node N3, to which the drain electrode of the driving transistor DT is connected, may be connected to a high potential voltage line VDDL and receive a high potential voltage VDD. The second node N2 to which the source electrode of the driving transistor DT is connected may be connected to the anode of the light emitting element 150.

The switching transistor SWT may transmit a data signal DATA (or data voltage) to the gate electrode (or first node N1) of the driving transistor DT. The switching transistor SWT may include a gate electrode that is connected to the gate line GL, a drain electrode that is connected to the data line DL, and a source electrode that is connected to the gate electrode (or first node N1) of the driving transistor DT. The switching transistor SWT may be turned on by a scan signal SCAN (or gate signal) provided from the gate line GL and transmit the data signal DATA (or data voltage) supplied from the data line D to the gate electrode (or first node N1) of the driving transistor DT.

The storage capacitor SC may maintain a voltage (data voltage) corresponding to the data signal DATA during one frame. One electrode of the storage capacitor SC may be connected to the first node N1 and the other electrode of the storage capacitor SC may be connected to the second node N2. That is, the storage capacitor SC may be connected between the gate electrode and the source electrode of the driving transistor DT.

Meanwhile, as a driving time of each sub-pixel SP increases, circuit elements such as the driving transistor DT and the like may be degraded. Accordingly, inherent characteristics of the circuit elements such as the driving transistor DT and the like may be changed. Here, the inherent characteristics of the circuit element may include a threshold voltage (Vth) of the driving transistor DT, a mobility (a) of the driving transistor DT, and the like. A change in the characteristics of the circuit element may cause a change in luminance of the corresponding sub-pixel SP. Therefore, the change in the characteristics of the circuit element may be used as the same concept as that of the change in luminance of the sub-pixel SP.

In addition, a degree of change in characteristics between circuit elements of the respective sub-pixels SP may be different according to a difference in degree of degradation of the respective circuit elements. The difference in the degree of change in characteristics between the circuit elements may cause luminance deviation between the sub-pixels SP. Therefore, a deviation in characteristics between the circuit elements may be used as the same concept as that of the luminance deviation between the sub-pixels SP. The change in characteristics between the circuit elements, that is, a change in luminance between the sub-pixels SP, and a deviation in characteristics between the circuit elements, that is, the luminance deviation between the sub-pixels SP may cause defects such as a reduction in accuracy of luminance representation of the sub-pixels SP, or occurrence of screen abnormality.

Accordingly, in the display device 100 (see FIG. 1) according to an exemplary embodiment of the present disclosure, a sensing function for sensing characteristics of the sub-pixel SP and a compensation function for compensating the characteristics of the sub-pixel SP may be provided.

For example, as shown in FIG. 2, the sub-pixel SP may further include the sensing transistor SET for controlling a voltage state of the source electrode of the driving transistor DT.

The sensing transistor SET is connected between the source electrode of the driving transistor DT and a reference voltage line RVL that supplies a reference voltage Vref, and may include a gate electrode that is connected to the gate line GL. Accordingly, the sensing transistor SET is turned on by a sensing signal SENSE applied through the gate line GL and may provide the reference voltage Vref supplied through the reference voltage line RVL to the source electrode of the driving transistor DT. Also, the sensing transistor SET may be used as one of voltage sensing paths for the source electrode of the driving transistor DT.

In this manner, the reference voltage Vref may be applied to the source electrode of the driving transistor DT through the sensing transistor SET that is turned on by the sensing signal SENSE. Also, a voltage for sensing the threshold voltage (Vth) of the driving transistor DT or the mobility (a) of the driving transistor DT may be detected through the reference voltage line RVL. In addition, the data driver 130 (see FIG. 1) of the display device 100 (see FIG. 1) may compensate for the data signal DATA according to the detected amount of change in the threshold voltage (Vth) of the driving transistor DT or the mobility (a) of the driving transistor DT.

Meanwhile, as shown in FIG. 2, the switching transistor SWT and the sensing transistor SET included in the sub-pixel SP may share one gate line GL. That is, the switching transistor SWT and the sensing transistor SET may be connected to the same gate line GL and receive the same signal (the same gate signal). For convenience of description, a signal that is applied to the gate electrode of the switching transistor SWT has been referred to as the scan signal SCAN, and a signal that is applied to the gate electrode of the sensing transistor SET has been referred to as the sensing signal SENSE described above. However, the scan signal SCAN and the sensing signal SENSE that are applied to one sub-pixel SP are the same signal transmitted through the same gate line GL.

Meanwhile, this is merely exemplary, and embodiments of the present disclosure are not limited thereto. For example, only the switching transistor SWT may be connected to the gate line GL, and the sensing transistor SET may be connected to a separate sensing line. Accordingly, the scan signal SCAN may be applied to the switching transistor SWT through the gate line GL, and the sensing signal SENSE may be applied to the sensing transistor SET through the sensing line.

Hereinafter, as shown in FIG. 2, descriptions will be made based on that the switching transistor SWT and the sensing transistor SET included in the sub-pixel SP share one gate line GL. Accordingly, in the following description, the scan signal SCAN and the sensing signal SENSE are defined as gate signals GATE1, GATE2, GATE3, and GATE4.

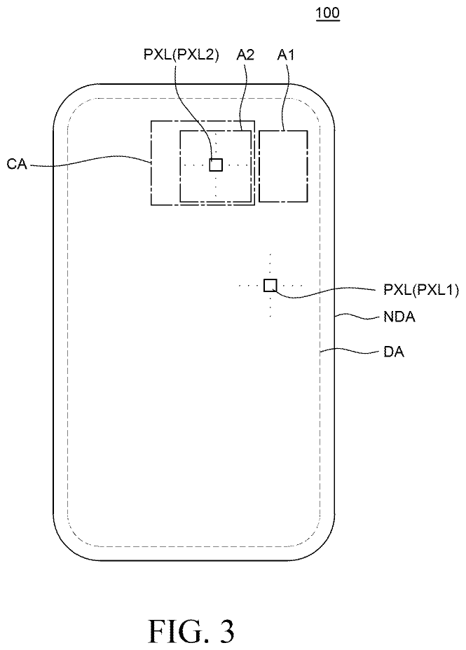

FIG. 3 is a schematic plan view of a display device according to an exemplary embodiment of the present disclosure.

Referring to FIG. 3, the display device 100 may include a display panel including a display area DA and a non-display area NDA. A plurality of pixels may be disposed in the display area DA. For example, the plurality of pixels may include one or more light emitting elements. The display device 100 may display an image on the display area DA by driving the pixels in response to input image data.

In an exemplary embodiment, at least a portion of the display area DA may be defined as a sensor area CA. For example, a partial area of the display area DA may be defined as the sensor area CA. For example, an entire area of the display area DA may be defined as the sensor area CA. The sensor area CA is at least a portion of the display area DA and may include the plurality of pixels. A sensor module (e.g., an image sensor or an infrared sensor) or a camera module may be additionally disposed in the sensor area CA.

In an exemplary embodiment, the sensor module may be provided on a rear surface of the display panel. The display panel may display an image through a front surface thereof and detect light incident on the front surface through the sensor module provided on the rear surface thereof. The sensor module may be formed at a location corresponding to a light-transmissive area OPN of the display panel.

In an exemplary embodiment, the sensor area CA may include light-transmissive areas OPN. At least a portion of the sensor area CA may be configured with the light-transmissive area OPN. The sensor module may be disposed at a location corresponding to the light-transmissive area OPN. In addition, the sensor module may be disposed at a location corresponding to at least a portion of the light-transmissive areas OPN. Since the light-transmissive area OPN has light transmittance higher than those of other areas, the sensor module provided at the corresponding location can detect relatively more light that is incident on the front surface, compared to a case where the sensor module is disposed in the other areas.

In an exemplary embodiment, the sensor module may overlap at least a portion of the pixels disposed in the sensor area CA or may be disposed around the pixels. For example, at least a portion of the sensor modules may be disposed to overlap the light-transmissive areas OPN between the pixels disposed in the sensor area CA.

The non-display area NDA is an area located around the display area DA, and may mean a remaining area other than the display area DA. The non-display area NDA may include a line area, a pad area, and/or various dummy areas.

The display device 100 may use the sensor module configured in the sensor area CA constituting at least a portion of the display area DA as a front sensor. The display device 100 may obtain an image of an object located in front of the display panel using the front sensor. Since not only the sensor module but also the plurality of pixels are disposed in the sensor area CA, the display device 100 may display an image even throughout the sensor area CA where the sensor module is located.

In an exemplary embodiment, first pixels PXL1 may be disposed across the display area DA, while second pixels PXL2 other than the first pixels PXL1 may be disposed across the sensor area CA. The first pixels PXL1 and the second pixels PXL2 may have substantially the same structure. According to an exemplary embodiment, unlike the first pixels PXL1 disposed across the display area DA, the light-transmissive areas OPN and a transparent electrode HE for forming the light-transmissive areas OPN may be disposed between the second pixels PXL2.

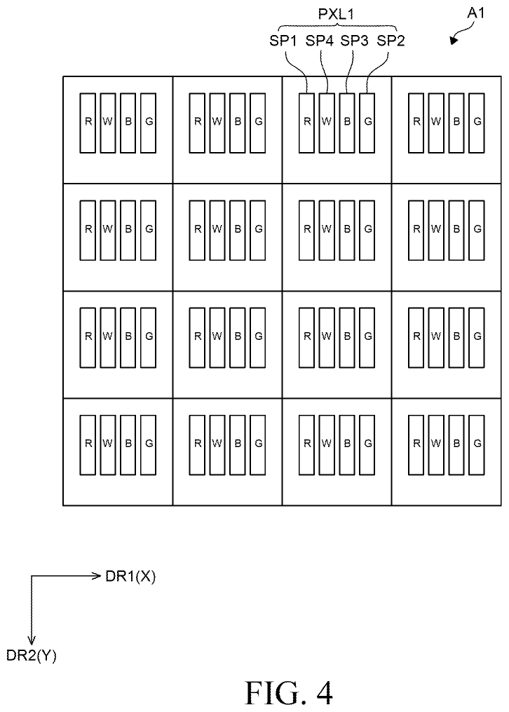

Meanwhile, the display area DA in the present disclosure may be divided into a first display area and a second display area. The first display area may be defined as a remaining area other than the sensor area CA, and the second display area may be defined as an area corresponding to the sensor area CA. Hereinafter, an implementation example of the first display area will be described with reference to FIG. 4, and various implementation examples that can be implemented in the second display area will be described with reference to FIGS. 4 to 9.

FIG. 4 is an enlarged plan view illustrating an implementation example of area A1 of FIG. 3.

Specifically, the area A1 is a portion of the first display area, and FIG. 4 is a view for explaining pixel arrangements in the first display area. Referring to FIG. 4, a plurality of the first pixels PXL1 may be disposed in a matrix manner on the display area DA. The first pixels PXL1 may be disposed in a first direction DR1. The first direction DR1 may be an X-axis direction. Also, the first pixels PXL1 may be disposed in a second direction DR2. The second direction DR2 may be a Y-axis direction. Based on the area A1, since the sensor module is not provided on the rear surface of the display panel, the light-transmissive area OPN is not formed therein.

The first pixels PXL1 may include a plurality of sub-pixels. For example, the first pixel PXL1 may include a first sub-pixel, a second sub-pixel, a third sub-pixel, and a fourth sub-pixel. The first sub-pixel may be a red sub-pixel, the second sub-pixel may be a green sub-pixel, the third sub-pixel may be a blue sub-pixel, and the fourth sub-pixel may be a white sub-pixel. The first to fourth sub-pixels may be disposed in a sequence of red, white, blue, and green sub-pixels along the first direction DR1, but the present disclosure is not limited thereto.

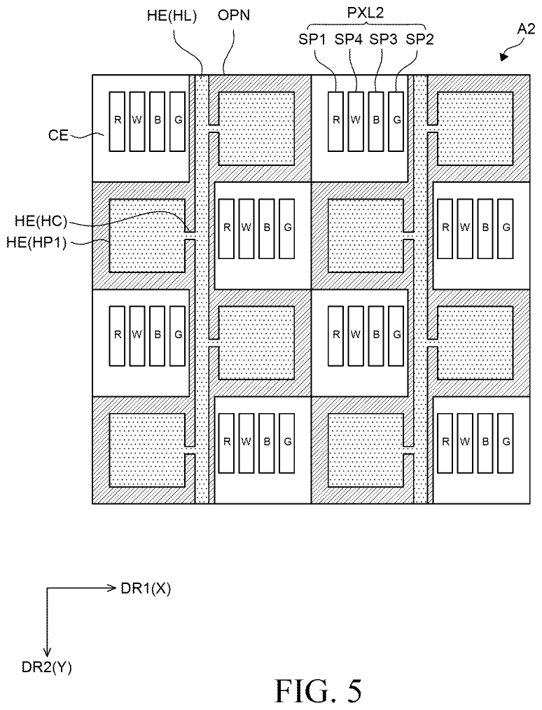

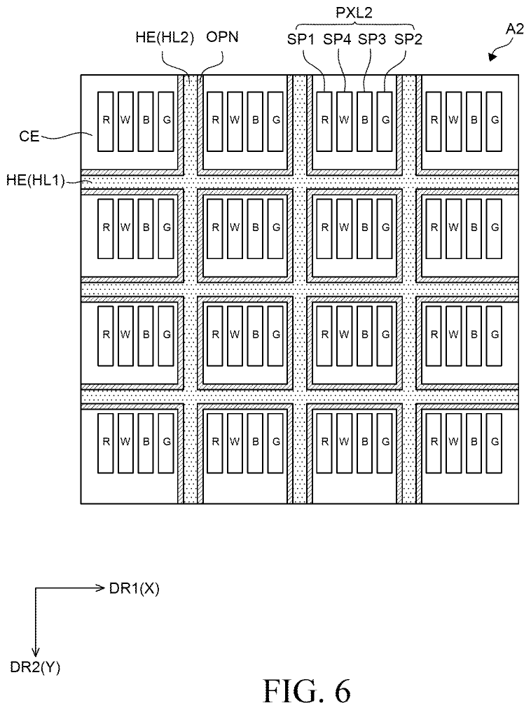

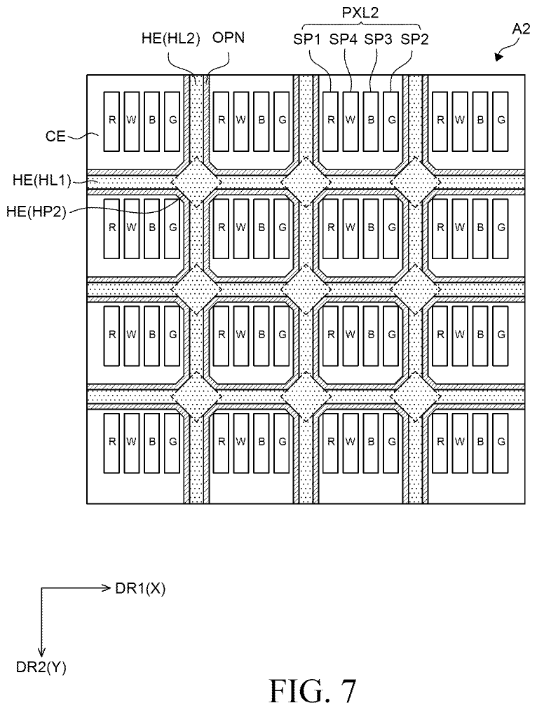

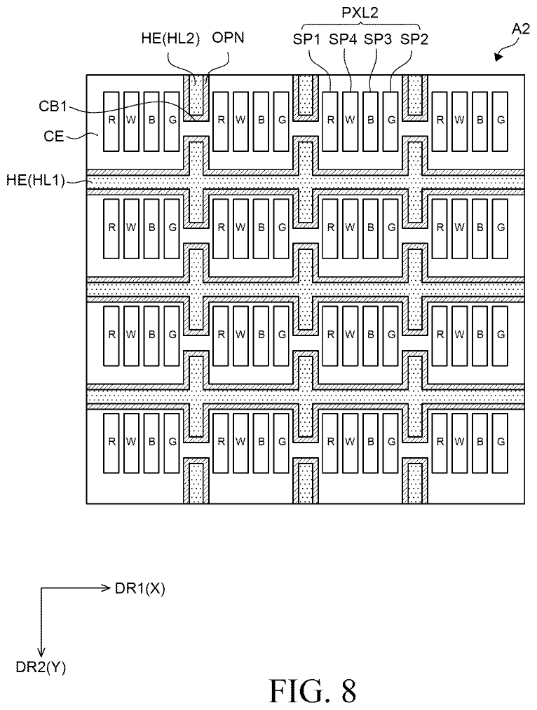

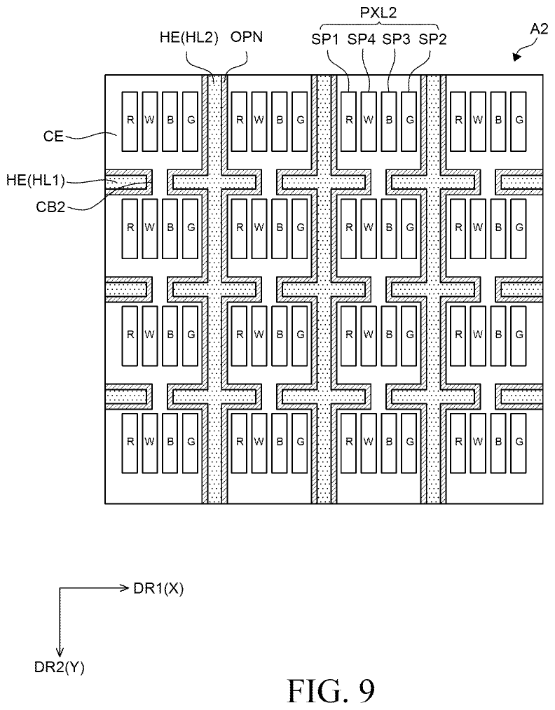

FIG. 5 is an enlarged plan view illustrating a first implementation example of area A2 of FIG. 3. FIG. 6 is an enlarged plan view illustrating a second implementation example of the area A2 of FIG. 3. FIG. 7 is an enlarged plan view illustrating a third implementation example of the area A2 of FIG. 3. FIG. 8 is an enlarged plan view illustrating a fourth implementation example of the area A2 of FIG. 3. FIG. 9 is an enlarged plan view illustrating a fifth implementation example of the area A2 of FIG. 3.

Specifically, the area A2 is a portion of the second display area, and FIGS. 5 to 9 are views for explaining pixel arrangements in the second display area. Referring to FIGS. 5 to 9, a plurality of the second pixels PXL2 may be disposed in a matrix manner on the sensor area CA. The second pixels PXL2 may be disposed in the first direction DR1. The second pixels PXL2 may be disposed in the second direction DR2. Based on the area A2, the sensor module may be provided on the rear surface of the display panel. To improve light transmittance of the sensor module, the light-transmissive area OPN may be formed in the area A2.

According to an exemplary embodiment, the second pixels PXL2 may include a plurality of sub-pixels. The second pixels PXL2 may have substantially the same configuration as the first pixels PXL1 of FIG. 4.

In an exemplary embodiment, the sensor area CA may include the plurality of second pixels PXL2 and the light-transmissive areas OPN separating at least portions of the second pixels PXL2. The light-transmissive areas OPN may be disposed between the second pixels PXL2. For example, the light-transmissive areas OPN may be alternately disposed with the second pixels PXL2 in the first direction DR1 and the second direction DR2. External light may be received by the sensor module through the light-transmissive area OPN. A resolution of the sensor area CA which is in proportion to an increase in an area of the light-transmissive area OPN may be smaller than that of the area A1 in FIG. 4.

In at least a portion of the light-transmissive area OPN, all of opaque metal electrodes other than the transparent electrode may be removed. Accordingly, lines of the pixel (e.g., the data line and gate line) may be disposed along an outer side of the light-transmissive area OPN. However, the present disclosure is not limited thereto, and the lines may also be disposed on the light-transmissive area.

In an exemplary embodiment, the light-transmissive area OPN may be formed by the transparent electrode HE. The transparent electrode HE can remove at least a portion of a layer structure overlapping or adjacent to the transparent electrode HE by using Joule heating. In particular, according to an exemplary embodiment, a cathode electrode CE provided on the light-transmissive area OPN can be removed using the transparent electrode HE. In the case of a display panel having a bottom emission structure, since the cathode electrode CE typically has a high light reflectance, light transmittance of the light-transmissive area OPN may be degraded even when the sensor module is mounted on a rear surface of the display panel. According to an exemplary embodiment of the present disclosure, the cathode electrode CE can be removed by applying Joule heating to the transparent electrode HE prepared in a predetermined or selected structure, and consequently, the light transmittance of the light-transmissive area OPN can be improved.

Meanwhile, to form a light-transmissive area in a conventional organic light emitting display device, a cathode electrode and an insulating film corresponding to the light-transmissive area are removed through a separate laser irradiation process. In this case, since equipment and process steps for a separate laser irradiation process should be introduced, a cost increase and inefficiency in the process occur. However, the organic light emitting display device according to an exemplary embodiment of the present disclosure uses the transparent electrode HE to form the light-transmissive area OPN. As will be described later, the transparent electrode HE may be formed on the same layer in the same process as other constituent electrodes such as an anode electrode. Therefore, the light-transmissive area OPN can be formed through Joule heating of the transparent electrode HE without a separate complicated additional process and equipment, and thus, process efficiency and optimization can be realized.

Referring to FIG. 5, the transparent electrode HE may include first transparent pads HP1 that are formed to protrude from transparent lines HL in a direction perpendicular thereto, and connection portions HC connecting the transparent lines HL and the first transparent pads HP1.

In an exemplary embodiment, the transparent lines HL may be formed to extend in the first direction DR1 or the second direction DR2. The first transparent pads HP1 may be formed in the direction perpendicular to the transparent lines HL. For example, when the transparent line HL is formed to extend in the first direction DR1, the first transparent pad HP1 that is electrically connected to the transparent line HL may be formed to protrude in the second direction DR2. The transparent line HL and the first transparent pad HP1 may be electrically connected to each other through the connection portion HC.

In an exemplary embodiment, the first transparent pads HP1 may be formed alternately with the second pixels PXL2 in the first direction DR1 and the second direction DR2. The first transparent pad HP1 may be disposed between the second pixels PXL2. In the case of the first implementation example shown in FIG. 5, the light-transmissive area OPN may be formed at a location where the second pixel PXL2 can be disposed. In the case of a 4×4 matrix, 16 pixels can be disposed in a typical display area (e.g., the area A1), but 8 pixels may be disposed in a sensor area (e.g., the area A2). As described above, when the first transparent pad HP1 is disposed in an area where the pixel is originally disposed, the light-transmissive area OPN having a large area can be formed, but the resolution can be degraded.

Meanwhile, although FIG. 5 exemplarily illustrates a case in which the transparent line HL extends vertically along the second direction DR2, various embodiments of the present disclosure are not limited thereto, and the transparent line HL may also extend in the first direction DR1.

Referring to FIG. 6, the transparent electrode HE may include first transparent lines HL1 and second transparent lines HL2. The first transparent line HL1 is a transparent line HL extending in the first direction DR1. The second transparent line HL2 is a transparent line HL extending in the second direction DR2. The first transparent line HL1 and the second transparent line HL2 may be orthogonal to each other.

In an exemplary embodiment, the first transparent line HL1 may be disposed between the second pixels PXL2. The first transparent line HL1 may be disposed between the second pixels PXL2 in the second direction DR2. In the second direction DR2, the second pixels PXL2 may be separated by the first transparent line HL1. In the first direction DR1, the second pixels PXL2 may be spatially separated from each other by the light-transmissive areas OPN.

In an exemplary embodiment, the second transparent line HL2 may be disposed between the second pixels PXL2. The second transparent line HL2 may be disposed between the second pixels PXL2 in the first direction DR1. In the first direction DR1, the second pixels PXL2 may be separated by the second transparent line HL2. In the second direction DR2, the second pixels PXL2 may be spatially separated from each other by the light-transmissive areas OPN.

In an exemplary embodiment, as the first transparent line HL1 and the second transparent line HL2 are orthogonal to each other, the second pixels PXL2 disposed in the area A2 may be spatially separated from each other.

Meanwhile, according to an exemplary embodiment, the sensor area (e.g., the area A2) and the display area (e.g., the area A1) may have substantially the same resolution. For example, when the light-transmissive areas OPN are not formed in areas where pixels are disposed, substantially the same number of pixels may be disposed in each of the sensor area CA and the display area DA.

Referring to FIG. 6, the light-transmissive areas OPN are disposed between the respective second pixels PXL2, but the light-transmissive areas OPN are not formed in areas where the second pixels PXL2 are disposed. For example, in the case of a 4×4 matrix, 16 pixels may be disposed in the area A2 in substantially the same manner as the area A1. Accordingly, the display panel may have substantially the same resolution in each of the sensor area CA and the display area DA.

Referring to FIG. 7, the transparent electrode HE may include the first transparent lines HL1, the second transparent lines HL2, and second transparent pads HP2. The first transparent line HL1 is a transparent line HL extending in the first direction DR1. The second transparent line HL2 is a transparent line HL extending in the second direction DR2. The first transparent line HL1 and the second transparent line HL2 may be orthogonal to each other. The second transparent pads HP2 may be disposed at each of intersections of the first transparent lines HL1 and the second transparent lines HL2. The second transparent pad HP2 may be formed in a triangular shape, a quadrangular shape, a circular shape or an elliptical shape.

In an exemplary embodiment, the first transparent line HL1 may be disposed between the second pixels PXL2. The first transparent line HL1 may be disposed between the second pixels PXL2 in the second direction DR2. In the second direction DR2, the second pixels PXL2 may be separated by the first transparent line HL1. In the second direction DR2, the second pixels PXL2 may be spatially separated from each other by the light-transmissive areas OPN.

In an exemplary embodiment, the second transparent line HL2 may be disposed between the second pixels PXL2. The second transparent line HL2 may be disposed between the second pixels PXL2 in the first direction DR1. In the first direction DR1, the second pixels PXL2 may be separated by the second transparent line HL2. In the first direction DR1, the second pixels PXL2 may be spatially separated from each other by the light-transmissive areas OPN.

In an exemplary embodiment, as the first transparent line HL1 and the second transparent line HL2 are orthogonal to each other, the second pixels PXL2 disposed in the area A2 may be spatially separated from each other.

Meanwhile, according to an exemplary embodiment, the sensor area (e.g., the area A2) and the display area (e.g., the area A1) may have substantially the same resolution. For example, when the light-transmissive areas OPN are not formed in areas where pixels are disposed, substantially the same number of pixels may be disposed in each of the sensor area CA and the display area DA.

Referring to FIG. 7, the light-transmissive areas OPN are disposed between the respective second pixels PXL2, but the light-transmissive areas OPN are not formed in the areas where the second pixels PXL2 are disposed. For example, in the case of a 4×4 matrix, 16 pixels may be disposed in the area A2 in substantially the same manner as the area A1. Accordingly, the display panel may have substantially the same resolution in each of the sensor area CA and the display area DA.

In the case of the display device 100 including the second transparent pads HP2, an area of the light-transmissive area OPN may be formed to be greater than that of a display device including no second transparent pads HP2 (e.g., the display device 100 of FIG. 6).

Referring to FIG. 8, the transparent electrode HE may include first transparent lines HL1 and second transparent lines HL2. The first transparent lines HL1 may extend in the first direction DR1. The second transparent lines HL2 may be repeatedly formed at predetermined or selected intervals in the second direction DR2. Specifically, the second transparent lines HL2 may be repeatedly formed with a predetermined or selected distance in the second direction DR2 so that two second pixels PXL2 adjacent in the first direction DR1 share the cathode electrode CE.

In an exemplary embodiment, the first transparent lines HL1 may be disposed between the second pixels PXL2. The first transparent lines HL1 may be disposed between the second pixels PXL2 in the second direction DR2. In the second direction DR2, the second pixels PXL2 may be separated by the first transparent lines HL1. In the second direction DR2, the second pixels PXL2 may be spatially separated from each other by the light-transmissive areas OPN.

In an exemplary embodiment, the second transparent lines HL2 may be disposed between the second pixels PXL2. The second transparent lines HL2 may be disposed between the second pixels PXL2 in the first direction DR1.

In an exemplary embodiment, the second transparent lines HL2 may have predetermined or selected separation spaces provided so that the cathode electrodes CE of the second pixels PXL2 are connected in the first direction DR1. Due to the predetermined or selected separation spaces provided in the second transparent lines HL2, the second pixels PXL2 disposed in the first direction DR1 may share the cathode electrode CE. The cathode electrodes CE of the second pixels PXL2 disposed in the first direction DR1 may be electrically connected by cathode bridges CB1 provided between the respective second pixels PXL2. A width of the cathode bridge CB1 in the first direction DR1 may correspond to a width of the light-transmissive area OPN in the first direction DR1. A width of the cathode bridge CB1 in the second direction DR2 may correspond to a distance between light-transmissive areas OPN formed in the second direction DR2.

According to an exemplary embodiment, a reference voltage line (not shown) may be electrically connected to the cathode electrode CE of each of the second pixels PXL2 through the cathode bridge CB1. The reference voltage line may be disposed to penetrate spaces between the pixels. The reference voltage line may be electrically connected to the cathode electrode CE through a contact hole (not shown). The cathode electrode CE may receive a reference voltage supplied from the reference voltage line through the contact hole.

Meanwhile, according to an exemplary embodiment, the sensor area (e.g., the area A2) and the display area (e.g., the area A1) may have substantially the same resolution. For example, when the light-transmissive areas OPN are not formed in areas where pixels are disposed, substantially the same number of pixels may be disposed in each of the sensor area CA and the display area DA.

Referring to FIG. 8, the light-transmissive areas OPN are disposed between the respective second pixels PXL2, but the light-transmissive areas OPN are not formed in areas where the second pixels PXL2 are disposed. For example, in the case of a 4×4 matrix, 16 pixels may be disposed in the area A2 in substantially the same manner as the area A1. Accordingly, the display panel may have substantially the same resolution in each of the sensor area CA and the display area DA.

Referring to FIG. 9, the transparent electrode HE may include first transparent lines HL1 and second transparent lines HL2. The first transparent lines HL1 may be repeatedly formed at predetermined or selected intervals in the first direction DR1. The second transparent lines HL2 may extend in the second direction DR2. Specifically, the first transparent lines HL2 may be repeatedly formed with a predetermined or selected distance in the first direction DR1 so that two second pixels PXL2 adjacent in the second direction DR2 share the cathode electrode CE.

In an exemplary embodiment, the first transparent lines HL1 may have predetermined or selected separation spaces provided so that the cathode electrodes CE of the second pixels PXL2 are connected in the second direction DR2. Due to the predetermined or selected separation spaces provided in the first transparent lines HL1, the second pixels PXL2 disposed in the second direction DR2 may share the cathode electrode CE. The cathode electrodes CE of the second pixels PXL2 disposed in the second direction DR2 may be electrically connected by cathode bridges CB2 provided between the respective second pixels PXL2. A width of the cathode bridge CB2 in the second direction DR2 may correspond to a width of the light-transmissive area OPN in the second direction DR2. A width of the cathode bridge CB2 in the first direction DR1 may correspond to a distance between light-transmissive areas OPN formed in the first direction DR1.

A remaining description of the fifth implementation example shown in FIG. 9 is substantially the same as that of the fourth implementation example shown in FIG. 8.

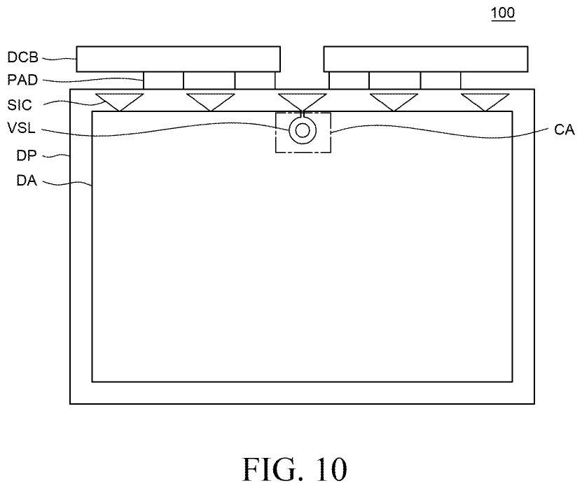

FIG. 10 is a plan view illustrating an example of the display device 100.

Referring to FIG. 10, the display device 100 may include a display panel DP, a driving circuit board DCB, a flexible circuit board PAD, and a source driving chip SIC. The display panel DP is substantially the same as the display panel DP described with reference to FIG. 1, and hereinafter, remaining components will be mainly described.

In an exemplary embodiment, the gate driver (the gate driver 120 in FIG. 1) is formed simultaneously with a manufacturing process of the transistors for driving the pixels, and may be mounted in the display panel DP in a form of an amorphous silicon TFT gate driver circuit (ASG) or oxide silicon TFT gate driver circuit (OSG). In an exemplary embodiment, the gate driver may be formed of a plurality of driving chips, mounted on the driving circuit board DCB, and connected to the display panel DP in a tape carrier package (TCP) method. In addition, the gate driver may be mounted on a substrate of the display panel DP in a chip on glass (COG) method.

In an exemplary embodiment, the data driver (the data driver 130 of FIG. 1) may include a plurality of source driving chips SIC. The source driving chips SIC may be disposed in a predetermined or selected area (e.g., an upper surface or a lower surface) adjacent to a long side of the display panel DP.

In an exemplary embodiment, flexible circuit boards PAD may be electrically connected to the driving circuit board DCB. Accordingly, the source driving chips may be electrically connected to the driving circuit board DCB through the flexible circuit board PAD.

In an exemplary embodiment, at least one of the source driving chips may be electrically connected to a reference voltage line. Specifically, the reference voltage line according to various embodiments of the present disclosure may include a first reference voltage line and a second reference voltage line. The first reference voltage line may be formed across the display area DA. The second reference voltage line may be formed as an auxiliary line VSL across the sensor area CA. The reference voltage line shown in FIG. 10 is an example of the second reference voltage line. In this disclosure, the second reference voltage line may be referred to as the auxiliary line VSL for convenience of explanation.

In an exemplary embodiment, the auxiliary line VSL may be disposed in the sensor area CA. The auxiliary line VSL may be formed in a mesh type. The auxiliary line VSL formed in the sensor area CA may be electrically connected to the cathode electrode CE of the pixel. For example, the auxiliary line VSL and the cathode electrode CE of the pixel may be directly connected. Other layer structures may not exist between the auxiliary line VSL and the cathode electrode CE of the pixel that are directly connected. A reference voltage may be provided to the auxiliary line VSL, and the reference voltage may also be provided to the cathode electrode CE that is electrically connected through the auxiliary line VSL.

In an exemplary embodiment, the auxiliary line VSL may be formed in the sensor area CA. In another exemplary embodiment, the auxiliary line VSL may be formed across an entirety of the display area DA as well as the sensor area CA.

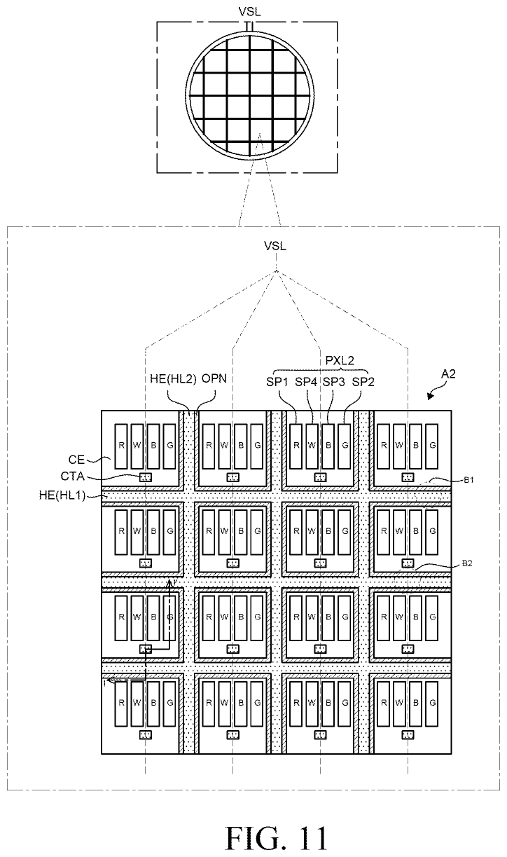

FIG. 11 is an enlarged plan view illustrating an implementation example of the area A2 including the auxiliary line of FIG. 10.

Referring to FIG. 11, the auxiliary line VSL may be formed in a mesh type. The auxiliary line VSL may be electrically connected to at least a portion or all of the second pixels PXL2 that are formed across the sensor area CA. The auxiliary line VSL may be electrically connected to the cathode electrode CE of each of the second pixels PXL2 through contact portions CTA.

FIG. 11 illustrates the sensor area CA (or A2 area) as the second implementation example described with reference to FIG. 6, but various embodiments of the present disclosure are not limited thereto. The auxiliary line VSL shown in FIG. 11 may be substantially equally applied to the first to five implementation examples described above with reference to FIGS. 5 to 9.

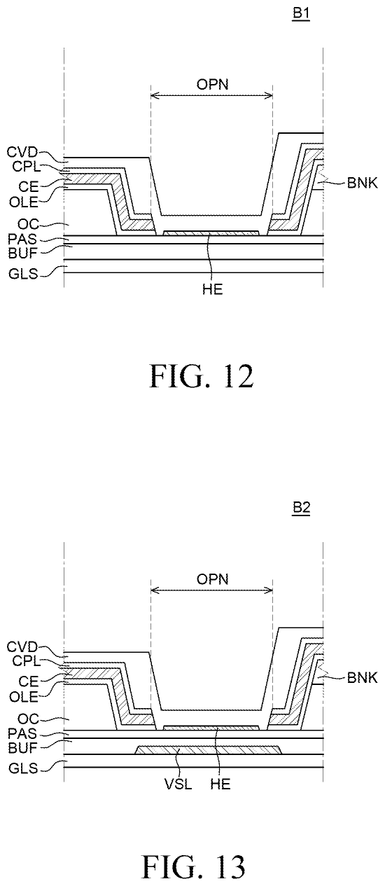

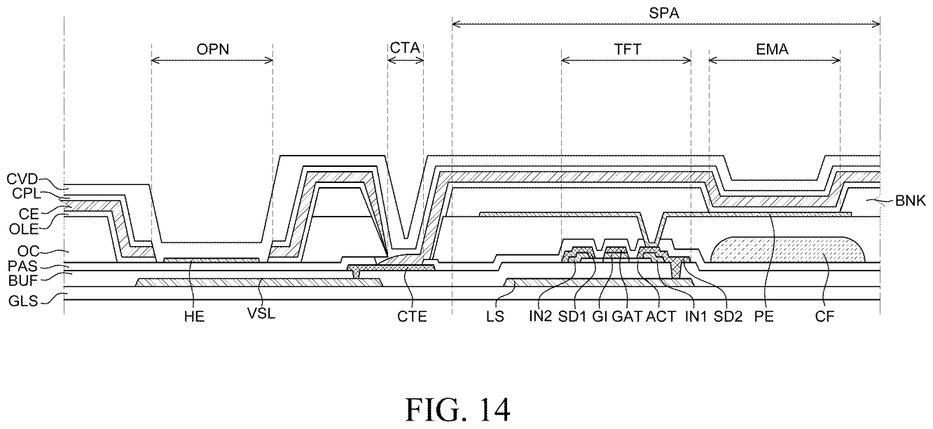

FIG. 12 is a cross-sectional view of area B1 of FIG. 11. FIG. 13 is a cross-sectional view of area B2 of FIG. 11. FIG. 14 is a cross-sectional view taken along line I-I′ of FIG. 11.

Referring to FIGS. 12 to 14, the display device according to various embodiments of the present disclosure may include various layer elements.

A substrate GLS may constitute a base member of the display panel. In an exemplary embodiment, the substrate GLS may be a rigid substrate GLS or a flexible substrate GLS, and materials or physical properties thereof are not limited. For example, the substrate GLS may be a rigid substrate GLS formed of glass or tempered glass, or a flexible substrate GLS formed of a thin film of plastic or a metallic material. The substrate GLS may be a transparent substrate GLS.

A buffer layer BUF may be disposed on the substrate GLS. The buffer layer BUF prevents penetration of oxygen or moisture from the outside and blocks impurities remaining on the substrate GLS from being introduced into the elements. When the buffer layer BUF does not reduce transmittance of the light-transmissive area OPN, the buffer layer BUF may also be formed in the light-transmissive area OPN. In addition, the buffer layer BUF may be omitted if there is no influence of external air or impurities such as moisture, and may be formed of a plurality of layers if beneficial.

A thin film transistor TFT including a gate electrode GAT, an active layer ACT, a source electrode SD2 and a drain electrode SD1 is disposed on the buffer layer BUF. For example, the active layer ACT is formed on the buffer layer BUF, and a gate insulating layer GI is formed on the active layer ACT to insulate the gate electrode GAT. In this case, a first insulating layer IN1 and a second insulating layer IN2 may be formed to partially insulate the active layer ACT from the source electrode SD2 and drain electrode SD1, but the present disclosure is not limited thereto. The gate insulating layer GI, the first insulating layer IN1, and the second insulating layer IN2 may be formed of substantially the same material in the same process. In addition, a passivation layer PAS for protecting the thin film transistor TFT is formed on the source electrode SD2 and the drain electrode SD1. However, in various embodiments of the present disclosure, a configuration and arrangement of the thin film transistor TFT may be changed as needed.

In addition, a light blocking layer LS may be disposed on the substrate GLS. The light blocking layer LS may be selected from a metallic material that blocks light, but is not limited thereto. The light blocking layer LS may be electrically connected to either the drain electrode SD1 or the source electrode SD2 through a contact hole formed in the buffer layer BUF. The light blocking layer LS, the gate electrode GAT, the drain electrode SD1, and the source electrode SD2 may be formed of substantially the same material, but are not limited thereto.

A planarization layer OC is disposed on the thin film transistor TFT. The planarization layer OC planarizes an upper portion of the thin film transistor TFT. In addition, the planarization layer OC covers a step between an area where the thin film transistor TFT is disposed and an area where the thin film transistor TFT is not disposed. The planarization layer OC may be formed of a transparent insulating resin. The planarization layer OC includes a contact hole for electrically connecting the thin film transistor TFT and an organic light emitting element ED.

The organic light emitting element ED is disposed on the planarization layer OC. The organic light emitting element ED is disposed on the planarization layer OC to be electrically connected to the thin film transistor TFT. The organic light emitting element ED includes an anode electrode PE, an organic light emitting layer OLE, and the cathode electrode CE.

The anode electrode PE may be disposed on the planarization layer OC. The anode electrode PE may be disposed on the planarization layer OC to correspond to an emission area. Also, the anode electrode PE may be formed to be separated for each emission area EMA. In this case, color mixing of light generated from adjacent emission areas EMA may be prevented.

The anode electrode PE may be formed of a transparent conductive material such as indium tin oxide (ITO), indium zinc oxide (IZO), or indium tin zinc oxide (ITZO), but is not limited thereto.

The anode electrode PE is electrically connected to the thin film transistor TFT through the contact hole of the planarization layer OC. For example, the anode electrode PE may be electrically connected to the source electrode SD2 of the thin film transistor TFT, but is not limited thereto.

The cathode electrode CE is disposed on the anode electrode PE. The cathode electrode CE supplies electrons to the organic light emitting layer OLE. For example, the cathode electrode CE may be formed of a transparent conductive material such as indium tin oxide (ITO), indium zinc oxide (IZO), indium tin zinc oxide (ITZO), zinc oxide (ZnO), and tin oxide (TO) or a metallic material including calcium (Ca), barium (Ba), aluminum (Al), silver (Ag) or the like, but the present disclosure is not limited thereto.

The cathode electrodes CE may be formed to correspond to a plurality of the emission areas EMA. In one example, the cathode electrodes CE may be formed to be connected without being separated for each of the plurality of emission areas. In one example, the cathode electrodes CE may be formed to be connected without being separated between at least a portion of the plurality of emission areas, and may be formed to be separated from each other with the light-transmissive areas OPN interposed therebetween, between the other portion of the plurality of emission areas.

In an exemplary embodiment, the transparent electrode HE may be formed of substantially the same material as the anode electrode PE. Accordingly, the transparent electrode HE may be formed substantially simultaneously in a process of forming the anode electrode PE.

The organic light emitting layer OLE is disposed between the anode electrode PE and the cathode electrode CE. The organic light emitting layer OLE is configured to emit light of the same color as that of the emission area corresponding thereto. The organic light emitting layer OLE may be separated for each of the plurality of emission areas and disposed on the anode electrode PE.

A bank BNK is disposed on the anode electrode PE and the planarization layer OC. The bank BNK serves to separate the emission areas adjacent to each other. In addition, the bank BNK serves to distinguish the emission area EMA and the light-transmissive area OPN that are adjacent to each other. The bank BNK may include an open portion exposing the transparent electrode HE. The open portion may be formed to correspond to the light-transmissive area. The open portion may be formed by a Joule heating process using the transparent electrode HE.

An encapsulation layer CPL may be disposed on the cathode electrode CE. The encapsulation layer CPL protects the organic light emitting element ED so that the organic light emitting element ED is not deteriorated by moisture penetrating from the outside. In addition, the encapsulation layer CPL planarizes an upper portion of the organic light emitting element ED. In addition, the encapsulation layer CPL covers a step between an area where the organic light emitting element ED is disposed and an area where the organic light emitting element ED is not disposed. The encapsulation layer CPL may be formed of a single layer or a plurality of layers. An inorganic encapsulation layer may be formed by depositing a material selected from silicon nitride (SiNx), silicon oxide (SiOx), silicon oxynitride (SiON), aluminum oxide (AlxOy) and the like, but the present disclosure is not limited thereto. For example, an organic encapsulation layer may be formed of a transparent resin selected from acrylic resins, epoxy resins, polyethylene resins, and the like, but is not limited thereto.

A color filter layer CF may be disposed on the passivation layer PAS. The color filter layer CF may be disposed in the plurality of emission areas EMA. To maintain high transmittance of the light-transmissive area OPN, the color filter layer CF may not be formed in the light-transmissive area OPN.

A protective layer CVD may be disposed on the encapsulation layer CPL. The protective layer CVD may be disposed to cover the pixel and a pixel circuit. The protective layer CVD may provide a flat surface while protecting the pixel and pixel circuit. The protective layer CVD may be formed of an organic material such as benzocyclobutene or photoacryl, but is not limited thereto.

Referring to FIGS. 12 and 13, in an exemplary embodiment, in the case of the cathode electrode CE that is at least a portion of a plurality of sub-pixels constituting one pixel, the cathode electrode CE can be formed not to be separated throughout the plurality of emission areas EMA. In an exemplary embodiment, in the case of cathode electrodes CE constituting different pixels (e.g., the second pixels PXL2), the cathode electrodes CE may be formed to be separated from each other. The cathode electrodes CE that are separated from each other may be spaced apart from each other with the light-transmissive area OPN interposed therebetween. This is because, in an exemplary embodiment, the cathode electrode CE is removed by Joule heating in a portion corresponding to the light-transmissive area OPN.

In an exemplary embodiment, the transparent electrode HE may be disposed on the planarization layer OC and the passivation layer PAS. In the portion corresponding to the light-transmissive area OPN, the transparent electrode HE may be disposed on the passivation layer PAS. Other layer elements (e.g., the organic light emitting layer OLE, the cathode electrode CE, and the encapsulation layer CPL) other than the protective layer CVD are not present on the transparent electrode HE. As the Joule heating process is applied to the transparent electrode HE, all of remaining layer elements deposited on the transparent electrode HE may be removed. The protective layer CVD is a layer element deposited after the Joule heating process and may be disposed on the transparent electrode HE. As described above, the display device according to various embodiments of the present disclosure includes the transparent electrode HE, and the light-transmissive areas OPN may be formed using the transparent electrode HE.

Referring to FIG. 13, in the case of an area through which the auxiliary line VSL passes (e.g., the area B2), the auxiliary line VSL may be disposed between the substrate GLS and the buffer layer BUF. That is, the auxiliary line VSL may be disposed below the transparent electrode HE. As the auxiliary line VSL and the transparent electrode HE are disposed farther from each other, it is advantageous in terms of design and processes.

Referring to FIGS. 13 and 14, in an exemplary embodiment, the auxiliary line VSL may be disposed on substantially the same layer as the light blocking layer LS. The auxiliary line VSL and the light blocking layer LS may be formed of substantially the same material, and the auxiliary line VSL may be formed together with the light blocking layer LS in a process of forming the light blocking layer LS. Also, although not shown, the auxiliary line VSL may be formed together with the gate electrode GAT, the source electrode SD1, and/or the drain electrode SD2 in a process of forming the gate electrode GAT, the source electrode SD1, and/or the drain electrode SD2. In this case, the auxiliary line VSL may be formed on substantially the same layer as the gate electrode GAT, the source electrode SD1 and/or the drain electrode SD2.

Referring to FIGS. 11 and 14, the second pixels PXL2 may include the contact portions CTA, and the cathode electrodes CE constituting the second pixels PXL2 may be electrically connected to the auxiliary line VSL. The auxiliary line VSL may be electrically connected to the plurality of second pixels PXL2.

Referring to FIG. 14, a contact hole may be formed at a location corresponding to the contact portion CTA. In addition, a contact electrode CTE may be disposed at a location corresponding to the contact portion CTA. In an exemplary embodiment, the contact hole may be formed in the passivation layer PAS. The auxiliary line VSL may be exposed through the contact hole formed in the passivation layer PAS. The contact electrode CTE may be formed on a contact hole provided in the buffer layer BUF. The contact electrode CTE may be electrically connected to the auxiliary line VSL through the contact hole. The contact electrode CTE may also be electrically connected to the cathode electrodes CE of the second pixels PXL2. As described above, the auxiliary line VSL may be electrically connected to the cathode electrode CE of each second pixel PXL2 through the contact electrode CTE. An electrical connection between the cathode electrode CE and the contact electrode CTE may be formed by a welding process, a drilling process, or an undercut process.

The exemplary embodiments of the present disclosure can also be described as follows:

According to an aspect of the present disclosure, there is provided an organic light emitting display device. The organic light emitting display device comprises a substrate including a display area; and pixels disposed in the display area on the substrate. The display area includes a sensor area including light-transmissive areas. The sensor area includes a transparent electrode disposed between the pixels. And, the transparent electrode overlaps the light-transmissive areas.

The transparent electrode may include a transparent line and first transparent pads. The transparent line may extend in either a first direction or a second direction. The first transparent pads may be formed to protrude in the second direction or the first direction that is perpendicular to the transparent line. The transparent line and the first transparent pads may be electrically connected through connection portions.

The first transparent pads may be alternately formed with the pixels disposed in the sensor area in the first direction.

The first transparent pads may be alternately formed with the pixels disposed in the sensor area in the second direction.

The light-transmissive areas overlapping the first transparent pads may be alternately formed with the pixels disposed in the sensor area along the first direction or the second direction. The number of the pixels included in a predetermined or selected area of the display area may be at least twice the number of the pixels included in the same area of the sensor area.

The transparent electrode may include first transparent lines extending in a first direction and second transparent lines extending in a second direction. The first transparent lines and the second transparent lines may be disposed between the pixels.

Cathode electrodes of the pixels disposed in the sensor area may be spaced apart and physically separated from cathode electrodes of the pixels adjacent in the first direction or the second direction.

The transparent electrode may further include second transparent pads, and the second transparent pads may be formed at intersections of the first transparent lines and the second transparent lines.

The transparent electrode may include first transparent lines extending in a first direction and second transparent lines repeatedly formed at predetermined or selected intervals in a second direction perpendicular to the first direction.

Cathode electrodes of the pixels disposed in the first direction may be electrically connected to each other through a cathode bridge having a width corresponding to the predetermined or selected interval.

Cathode electrodes of the pixels in the sensor area may be physically separated by the light-transmissive areas, and the cathode electrodes of the pixels may be electrically connected to an auxiliary line formed across the sensor area.

The auxiliary line may be formed in a mesh type, and the auxiliary line may be electrically connected to at least a portion of the pixels disposed in the sensor area.

A reference voltage may be supplied to the auxiliary line.

The auxiliary line may be electrically connected to the cathode electrodes of the pixels disposed in the sensor area through contact holes.

The transparent electrode and an anode electrode constituting the pixel may be formed of the same material.

The organic light emitting display device may further comprise a protective layer disposed on the pixels. The transparent electrode directly may contact the passivation layer in the light-transmissive areas.

An organic light emitting display device according to another exemplary embodiment of the present disclosure includes a plurality of pixels disposed in a display area and a sensor area, a driving circuit board for driving the plurality of pixels, a transparent electrode for Joule heating disposed between the respective pixels, and a sensor module located on a rear surface of the sensor area, and the sensor area includes light-transmissive areas located between the plurality of pixels and formed by applying Joule heating to the transparent electrode.

According to another feature of the present disclosure, the transparent electrode may include a transparent line and first transparent pads, the transparent line may extend in either a first direction or a second direction, and the first transparent pads may be formed to protrude in the second direction or the first direction that is perpendicular to the transparent line. In addition, the transparent line and the first transparent pads may be electrically connected through connection portions.

According to still another feature of the present disclosure, the first transparent pads may be alternately formed with the pixels formed across the sensor area in the first direction.

According to still another feature of the present disclosure, the first transparent pads may be alternately formed with the pixels formed across the sensor area in the second direction.

According to still another feature of the present disclosure, the light-transmissive areas formed by the first transparent pads may be alternately formed with the pixels formed across the sensor area in the first direction or the second direction. Also, the number of the pixels included in a predetermined or selected area of the display area may be at least twice the number of the pixels included in the same area of the sensor area.

According to still another feature of the present disclosure, the transparent electrode includes first transparent lines extending in the first direction and second transparent lines extending in the second direction, and the first transparent lines and the second transparent lines may be disposed between the pixels.

According to still another feature of the present disclosure, cathode electrodes of the pixels disposed on the sensor area may be spaced apart and physically separated from cathode electrodes of the pixels adjacent to each other in the first direction or the second direction.

According to still another feature of the present disclosure, the transparent electrode may further include second transparent pads, and the second transparent pads may be formed at intersections of the first transparent lines and the second transparent lines.

According to still another feature of the present disclosure, the transparent electrode may include first transparent lines extending in the first direction and second transparent lines repeatedly formed at predetermined or selected intervals in the second direction perpendicular to the first direction.

According to still another feature of the present disclosure, based on the first transparent lines, the cathode electrodes of the pixels disposed in the second direction may be electrically connected to each other.

According to still another feature of the present disclosure, the cathode electrodes of the pixels disposed in the second direction may be electrically connected to each other through a cathode bridge, and a width of the cathode bridge may be configured to be equal to a width of the light-transmissive area formed by the second transparent lines.

According to still another feature of the present disclosure, based on the first transparent lines, the cathode electrodes of the pixels disposed in the first direction may be spaced apart from each other.

According to still another feature of the present disclosure, the light-transmissive areas formed by the first transparent lines may be formed between the cathode electrodes of the pixels disposed in the first direction.

According to still another feature of the present disclosure, in the case of the pixels disposed in the sensor area, at least portions of the cathode electrodes constituting the pixels may be physically separated by the light-transmissive areas, and the cathode electrodes of the pixels may be electrically connected to an auxiliary line formed across the sensor area.

According to still another feature of the present disclosure, the auxiliary line is formed in a mesh type, and the auxiliary line may be electrically connected to at least a portion or all of the pixels disposed in the sensor area.

According to still another feature of the present disclosure, a reference voltage may be supplied to the auxiliary line.

According to still another feature of the present disclosure, the auxiliary line is electrically connected to the cathode electrodes of the pixels disposed in the sensor area through contact portions, and the contact portion may include a contact electrode and a contact hole. Also, the contact electrode may be electrically connected to the cathode electrode and the auxiliary line.

According to still another feature of the present disclosure, one or more layer elements may be disposed between the auxiliary line and the transparent electrode.

According to still another feature of the present disclosure, the transparent electrode and an anode electrode constituting the pixel may be formed of the same material.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light emitting display device, comprising:
a substrate including a display area; and
a plurality of pixels disposed in the display area on the substrate,
wherein the display area includes a sensor area including a plurality of light-transmissive areas,
wherein the sensor area includes a transparent electrode disposed between the plurality of pixels, and
wherein the transparent electrode overlaps the plurality of light-transmissive areas.

2. The organic light emitting display device of claim 1, wherein the transparent electrode includes a transparent line and a plurality of first transparent pads,
wherein the transparent line extends in either a first direction or a second direction,
wherein the plurality of first transparent pads are formed to protrude in the second direction or the first direction that is perpendicular to the transparent line, and
wherein the transparent line and the plurality of first transparent pads are electrically connected to each other through a plurality of connection portions.

3. The organic light emitting display device of claim 2, wherein the plurality of first transparent pads is alternately formed with the plurality of pixels disposed in the sensor area in the first direction.

4. The organic light emitting display device of claim 2, wherein the plurality of first transparent pads is alternately formed with the plurality of pixels disposed in the sensor area in the second direction.

5. The organic light emitting display device of claim 2, wherein the plurality of light-transmissive areas overlapping the plurality of first transparent pads is alternately formed with the plurality of pixels disposed in the sensor area along the first direction or the second direction, and
wherein number of pixels included in a selected area of the display area is at least twice number of pixels included in a same area of the sensor area.

6. The organic light emitting display device of claim 1, wherein the transparent electrode includes a plurality of first transparent lines extending in a first direction and a plurality of second transparent lines extending in a second direction, and
wherein the plurality of first transparent lines and the plurality of second transparent lines are disposed between the plurality of pixels.

7. The organic light emitting display device of claim 6, wherein cathode electrodes of the plurality of pixels disposed in the sensor area are spaced apart and physically separated from cathode electrodes of the plurality of pixels adjacent in the first direction or the second direction.

8. The organic light emitting display device of claim 6, wherein the transparent electrode further includes a plurality of second transparent pads, and the plurality of second transparent pads is formed at a plurality of intersections of the plurality of first transparent lines and the plurality of second transparent lines.

9. The organic light emitting display device of claim 1, wherein the transparent electrode includes a plurality of first transparent lines extending in a first direction and a plurality of second transparent lines repeatedly formed at selected intervals in a second direction perpendicular to the first direction.

10. The organic light emitting display device of claim 9, wherein a plurality of cathode electrodes of the plurality of pixels disposed in the first direction are electrically connected to each other through a cathode bridge having a width corresponding to the selected intervals.

11. The organic light emitting display device of claim 1, wherein a plurality of cathode electrodes of the plurality of pixels in the sensor area are physically separated from each other by the plurality of light-transmissive areas, and
wherein the plurality of cathode electrodes of the plurality of pixels are electrically connected to an auxiliary line formed across the sensor area.

12. The organic light emitting display device of claim 11, wherein the auxiliary line is formed in a mesh type, and
wherein the auxiliary line is electrically connected to at least a portion of the plurality of pixels disposed in the sensor area.

13. The organic light emitting display device of claim 11, wherein a reference voltage is supplied to the auxiliary line.

14. The organic light emitting display device of claim 11, wherein the auxiliary line is electrically connected to the plurality of cathode electrodes of the plurality of pixels disposed in the sensor area through a plurality of contact holes.

15. The organic light emitting display device of claim 1, wherein the transparent electrode and an anode electrode of the pixel are formed of the same material.

16. The organic light emitting display device of claim 1, further comprising:
a protective layer disposed on the plurality of pixels,
wherein the transparent electrode directly contacts a passivation layer in the plurality of light-transmissive areas.

17. An organic light emitting display device, comprising:
a substrate including a display area; and
a plurality of pixels disposed in the display area on the substrate,
wherein the display area includes a sensor area including a plurality of light-transmissive areas,
wherein the sensor area includes a transparent electrode disposed between the plurality of pixels, and
the plurality of the light-transmissive areas is formed by applying Joule heating to the transparent electrode.
